(19) United States
(12) Patent Application Publication
(10) Pub. No.: US 2023/0395735 A1
(43) Pub. Date: Dec. 7, 2023

(54) SEMICONDUCTOR DEVICES WITH GRADED INTERFACE REGIONS

(71) Applicant: NATIONAL RESEARCH COUNCIL OF CANADA, Ottawa (CA)

(72) Inventor: Alexandre W. Walker, Kew Gardens, NY (US)

(21) Appl. No.: 18/250,124

(22) PCT Filed: Oct. 19, 2021
(86) PCT No.: PCT/IB2021/059637

§ 371 Date: Apr. 21, 2023

Related U.S. Application Data
(60) Provisional application No. 63/104,743, filed on Oct. 23, 2020.

(51) Int. Cl. H01L 31/0352; H01L 31/0304; H01L 31/18

(52) U.S. Cl. CPC H01L 31/03529; H01L 31/03046; H01L 31/1844

(57) ABSTRACT

An example semiconductor device includes: a first layer comprising a first semiconductor material; a second layer comprising a second semiconductor material; and an interface region disposed between the first layer and the second layer and corresponding to an expected depletion region of an interface between the first semiconductor material and the second semiconductor material, the interface region comprising a gradation from the first semiconductor material to the second semiconductor material; and wherein the interface region is configured to reduce Shockley-Read-Hall recombination in the semiconductor device.

### FIELD

The specification relates generally to semiconductor devices, and more particularly to semiconductor devices with graded interface regions.

### BACKGROUND

Semiconductor devices, such as photodetectors, may employ semiconductor materials forming a p-n junction to function. The p-n junction introduces a depletion region in which charge carriers drift across the interface between the two semiconductor materials. The recombination in this depletion region may contribute to the dark current which introduces noise experienced by the semiconductor device; this limits the signal to noise ratio of the semiconductor device.

### SUMMARY

According to an aspect of the present specification, a semiconductor device is provided. The semiconductor device includes: a first layer comprising a first high bandgap semiconductor material; a second layer comprising a second low bandgap semiconductor material; and an interface region disposed between the first layer and the second layer and corresponding to an expected depletion region between the first semiconductor material and the second semiconductor material, the interface region comprising a gradation from the first semiconductor material composition to the second semiconductor material composition; and wherein the interface region is configured to reduce Shockley-Read-Hall recombination in the semiconductor device.

According to another aspect of the present specification, a photodetector is provided. The photodetector includes: at least one detector cell, each detector cell comprising: a first semiconductor material having a p-doped region; an n-type semiconductor material configured to interface with the p-doped region to form a depletion region; and an interface region contained in the depletion region comprising a gradation of alloys from the p-type semiconductor material to the n-type semiconductor material, the interface region configured to increase a bandgap between the p-type semiconductor material and the n-type semiconductor material and decrease the dark current of the photodetector.

### BRIEF DESCRIPTION OF DRAWINGS

Implementations are described with reference to the following figures, in which:

FIG. 1A depicts an example semiconductor device with a graded interface region;

FIG. 1B depicts an example semiconductor device with no interface region;

FIG. 2 depicts the intermediate layers of the interface layer in the semiconductor device of FIG. 1A;

FIG. 3 depicts a flowchart of an example method of manufacturing a semiconductor device with a graded interface region;

FIG. 4 depicts a plot charting bandgap and intrinsic carrier concentration by position in a semiconductor device with a graded interface region; and

FIG. 5 depicts a plot charting the dark current experienced by semiconductor devices with a graded interface region and semiconductor devices with no interface region.

### DETAILED DESCRIPTION

Semiconductor devices are continually being optimized to reach state-of-the-art performance. One performance metric contributing to noise in semiconductor devices is the dark current experienced by each pixel in a semiconductor photodetector device. Semiconductor devices having p-n junctions have a depletion region in which recombination, and particularly Shockley-Read-Hall recombination is high, and leads to dark current impeding performance of the semiconductor device. In particular, the depletion region recombination may dominate the total dark current.

Existing solutions may provide thinner semiconductor devices that result in reduced noise at the cost of external quantum efficiency or absorption. Another method of reducing noise is to improve material quality, but it is believed to be near optimal and further improvements are costly. Yet another method of reducing noise is to reduce the area of the junction to reduce the dark current, but may decrease quantum efficiency, and in the case of photodetector arrays, increase cross-talk between pixels; both of these imply a trade-off of one performance metric for another. Further, none of these solutions address the significance of the contribution of the junction and/or depletion region to the total dark current experienced by the semiconductor device.

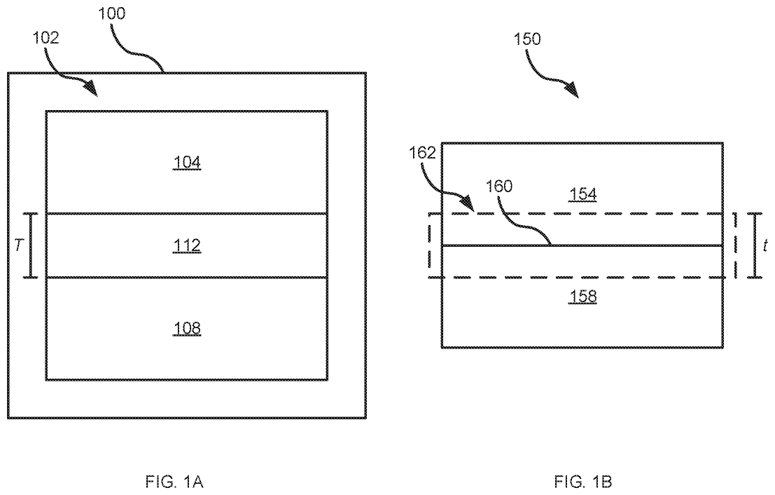

FIG. 1A depicts an example semiconductor device 100 in accordance with the present specification. The semiconductor device 100 may be, for example, a photodetector for use, for example, in short wave infrared applications or the like. The semiconductor device 100 has at least one cell 102 (e.g., a detector cell forming a pixel of a photodetector) containing an epitaxial structure configured to reduce Shockley-Read-Hall recombination in the semiconductor device. Advantageously, the reduction of Shockley-Read-Hall recombination allows for a reduction in the dark current experienced by the cell 102, and hence increases performance of the cell 102 and the semiconductor device 100. In some examples, the semiconductor device 100 may include a plurality of active cells 102, for example forming pixels of the photodetector. Preferably, the cell(s) 102 have a junction perimeter-to area ratio of less than about 10000 per centimeter, and preferably less than about 1000 per centimeter. Larger cells having smaller perimeter-to-area ratio may particularly benefit from the structure described herein, as described further below.

The cell 102 includes a first layer 104 formed of a first semiconductor material, a second layer 108 formed of a second semiconductor material, and an interface region 112 disposed between the first layer 104 and the second layer 108.

The first layer 104 and the second layer 108 may be formed, for example, of n-type semiconductors with p-dopant diffused through the one of the layers and into the second layer 108 to form a p-n junction. For example, the first layer 104 may be formed of indium phosphide (InP) and the second layer 108 may be formed of indium gallium arsenide (InGaAs). In other examples, other p- and n-type semiconductor materials and/or dopants are contemplated. In particular, the first and second semiconductor materials may be selected according to the particular application of the semiconductor device, such as for use as a photodetector or the like. In such an example, the first layer 104 and the second layer 108 are configured to form a p-n junction at which photodetection takes place. When the first semiconductor material and the second semiconductor material interface to form a p-n junction, they also form a depletion region in which charge carriers have been diffused away from the respective semiconductor material. In particular, the depletion region formed by two semiconductor materials may vary based on the particular doping characteristics of the first and second semiconductor materials as well as their interaction with each other.

As will be appreciated, in some examples, the cell 102 may include further layers; for example, the cell 102 may include InP/InGaAs/InP sandwiched layers according to a particular practical application of the cell 102.

For example, referring to FIG. 1B, a cell 150 is depicted. The cell 150 includes a first layer 154 formed of the first semiconductor material (i.e., the same first semiconductor material forming the first layer 104) and a second layer 158 formed of the second semiconductor material (i.e., the same second semiconductor material forming the second layer 108). In the cell 150, the first semiconductor material and the second semiconductor material directly interface to form a classical p-n junction having a sharp interface 160 between the first and second semiconductor materials and creating a barrier to current flow. In the cell 150, a depletion region 162 is formed in which the charge carriers (i.e., the holes and the electrons of the p- and n-type semiconductor materials respectively) diffuse across the interface 160. This depletion region 162 has a thickness t that may vary, as described above, based on the characteristics of the first and second semiconductor materials and properties of their interaction with each other. For example, when the primary doping concentration of the semiconductor material(s) is low, the depletion region may increase.

Returning to FIG. 1A, the cell 102 of the semiconductor device 100 further includes the interface region 112. The interface region 112 is disposed between the first layer 104 and the second layer 108. The interface region 112 is formed of a compositionally graded material. In particular, the interface region 112 forms a gradation from the first semiconductor material of the first layer 104 to the second semiconductor material of the second layer 108. For example, the interface region 112 may include one or more alloys of the first semiconductor material and the second semiconductor material.

Additionally, the interface region 112 corresponds to the expected depletion region of an interface between the first semiconductor material and the second semiconductor material. That is, the interface region 112 corresponds to the depletion region 162 of the first semiconductor material and the second semiconductor material. Preferably, the interface region 112 extends substantially across the expected depletion region. That is, the interface region 112 has a thickness T that is substantially equal to the thickness t of the depletion region 162. For example, the interface region 112 may have a thickness of between about 100 nm and about 1000 nm. In other words, the interface region 112 may be said to be contained in the depletion region of the interface between the first semiconductor material and the second semiconductor material. Alternately, the depletion region may contain or comprise a bandgap gradient.

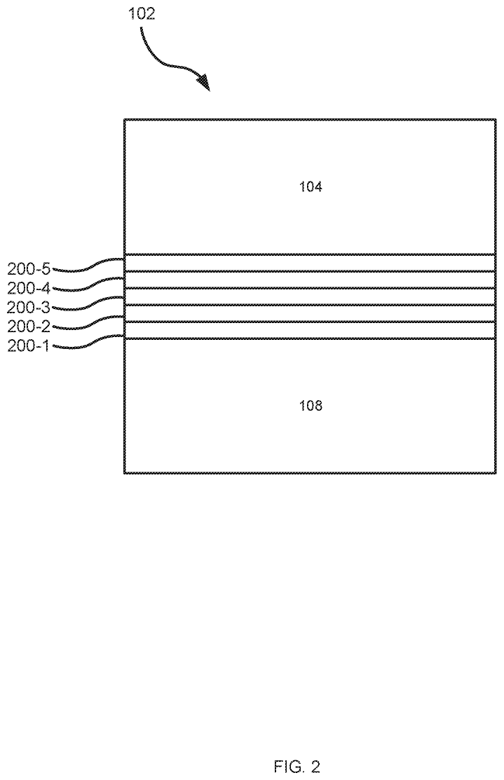

In some examples, the interface region 112 may include a stepwise gradation of intermediate layers of alloys of the first semiconductor material and the second semiconductor material. For example, FIG. 2 depicts the semiconductor device 100, wherein the interface region 112 includes intermediate layers 200-1, 200-2, 200-3, 200-4, and 200-5 (referred to collectively as intermediate layers 200 and generically as an intermediate layer 200).

Each of the intermediate layers 200 may be formed of an alloy of the first semiconductor material and the second semiconductor material. For example, when the first semiconductor material is indium gallium arsenide (InGaAs) and the second semiconductor material is indium phosphide (InP), the intermediate layers 200 may be formed of alloys of indium gallium arsenide phosphide (InGaAsP). In some examples, one or more of the intermediate layers may be formed of an alloy of indium gallium arsenic aluminum phosphide (InGaAsAIP). In particular, aluminum may be included in the alloy to further increase the bandgap of the interface region 112. As will be appreciated, in other examples, other alloys including other elements may also be included.

In particular, each intermediate layer 200 may be formed of an alloy having different proportions of each element, to create the gradation from the first semiconductor material to the second semiconductor material. That is, the intermediate layer 200-1 may have higher proportions of indium and phosphorus and lower proportions of gallium and arsenic, while the intermediate layer 200-3 has a relatively lower proportion of phosphorus and relatively higher proportions of gallium and arsenic, and the intermediate layer 200-5 has still lower proportions of indium and phosphorus and still higher proportions of gallium and arsenic. Preferably, the alloys forming each intermediate layer 200 are specific alloys of the first semiconductor material and the second semiconductor material having predetermined and/or standardized elemental compositions.

The present example depicts the interface region 112 as including five intermediate layers; in other examples, the interface region 112 may include more or fewer intermediate layers (e.g., 3, 10, 20 layers) as appropriate based on, for example, the size or thickness of the depletion region, the manufacturing capabilities, or other relevant factors. In still further examples, the interface region 112 may be linearly graded from the first semiconductor material to the second semiconductor material. That is, the interface region 112 may be composed of a mixture of the first semiconductor material and the second semiconductor material proportional to the respective distances from the first semiconductor material and the second semiconductor material.

The semiconductor device 100 having the epitaxial structure as described above allows for a reduction in dark current and hence an increase in performance of the semiconductor device 100. In particular, the depletion region of a cell having a classic p-n junction, such as the depletion region 162 of the cell 150, is predominantly affected by Shockley-Read-Hall recombination. By grading the interface region with at least one, and preferably a plurality of higher bandgap materials (i.e., relative to the lowest bandgap material), Shockley-Read-Hall recombination is substantially inhibited. Further, by extending the interface region substantially across the expected depletion region, recombination is inhibited across the depletion region of the cell. As the recombination in the depletion region contributes to a substantial portion of the dark current experienced by the semiconductor device 100, by reducing recombination in said depletion region, the significance of dark current noise in the semiconductor device 100 is reduced, and performance is therefore improved. Additionally, while the absorption region of the semiconductor device 100 is shifted, no potential barriers are introduced based on the graded and alloyed nature of the interface region, and hence sensitivity and quantum efficacy of the semiconductor device 100 is not strongly negatively influenced.

This is in contrast to other applications of grading the bandgap between semiconductor materials, such as the grading in avalanche photodiodes composed in a separate absorption, grading, and multiplication regions. In particular, the gradation is formed, not to allow the movement of charge carriers from one region to the next as fast as possible, but with higher bandgap material(s) compared to the absorption region over substantially the entirety of the depletion region to specifically reduce or inhibit recombination in the depletion region.

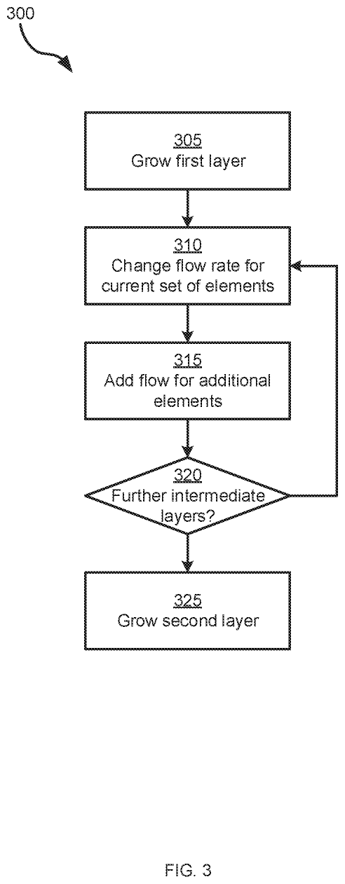

Referring now to FIG. 3, a flowchart of an example method 300 of growing a semiconductor device cell with a graded interface region according to the present specification is depicted. The method 300 will be described in relation to the semiconductor device 100 with reference to the components described in FIGS. 1 and 2.

At block 305, the first layer 104 is grown by providing a first set of elements at prescribed flow rates corresponding to a first semiconductor elemental composition. In particular, the first semiconductor material may have a first semiconductor elemental composition as selected by a manufacturer, according to an industry standard, or the like. Further, the elemental composition of the first semiconductor material may correspond to prescribed flow rates for the elements in the first set in order to grow the first semiconductor material in the desired elemental composition. For example, the first layer of InGaAs may be grown by providing a consistent flow of each of indium, gallium and arsenic to create a specific elemental composition of InGaAs. In other examples, flow rates may be modified during the growing operation according to the particular manufacturing or growing process.

At blocks 310, 315, and 320, the interface region 112 is grown. In particular, the interface region 112 is grown one intermediate layer 200 at a time by iterating through blocks 310, 315, and 320. As described above, preferably each intermediate layer 200 comprises specific alloys of the first semiconductor material and the second semiconductor material having predetermined elemental compositions. Accordingly, to grow each intermediate layer, the first set of elements and at least one additional element (i.e., the elements forming the alloy) are provided according to prescribed flow rates corresponding to the alloy's elemental composition.

Specifically, at block 310 the flow rate for the current set of elements (i.e., the elements forming the immediately preceding layer) is modified according to the prescribed flow rate for the alloy's elemental composition. In some examples, this may include reducing the flow rate of at least one element to zero (i.e., removing flow for a given element entirely). For example, to grow the first intermediate InGaAsP layer 200-1 from the first layer 104 of InGaAs, the flow rate of gallium and arsenic may be decreased, while the flow rate of indium is increased. Similarly, to grow the second intermediate InGaAsP layer 200-2 from the first intermediate InGaAsP layer 200-1, the flow rate of gallium and arsenic may be decreased further, while the flow rate of indium is increased further. Additionally, as the first intermediate InGaAsP layer 200-1 includes a flow of phosphorous, the flow rate of phosphorous may also be increased at block 310 when growing the second intermediate InGaAsP layer 200-2.

In other examples, only the flow rate of gallium may be decreased, and the flow rate of indium increased, while the flow rates of arsenic and phosphorous remain constant or may be increased. The adjustments to the flow rate at block 310 may be based on the specific elemental composition of the alloy and its prescribed method of growing.

At block 315, any additional elements of the intermediate layer 200 are provided according to the prescribed flow rate for the alloy's elemental composition. As will be appreciated, in order to grow the alloy, this step may be performed concurrently with block 310. For example, to grow the first intermediate InGaAsP layer 200-1 from the first layer 104 of InGaAs, a flow of phosphorous is provided at the prescribed flow rate for the elemental composition of the first intermediate layer 200-1. When growing the second intermediate InGaAsP layer 200-2 from the first intermediate InGaAsP layer 200-1, there are no additional new elements to be added, and hence block 315 may be skipped. In other examples, such as when an intermediate layer 200 includes aluminum to form an InGaAsAIP alloy, a flow of aluminum is provided at block 315.

At block 320, if further intermediate layers 200 are to be grown, the method 300 returns to block 310 to grow the next intermediate layer 200. If no further intermediate layers 200 are to be grown, the method 300 proceeds to block 325 to grow the second layer 108.

At block 325, the second layer 108 is grown. In particular, the flow rates for the current set of elements (i.e., the elements forming the immediately preceding intermediate layer 200), may be adjusted according to the prescribed flow rate for the elemental composition of the second semiconductor material. This may include removing flow for a given element entirely. Additionally, if applicable, any additional elements of the second semiconductor material are provided according to the prescribed flow rate for the elemental composition of the second semiconductor material. Preferably, the second semiconductor material may be formed of a second set of elements which is a subset of the alloy of the elements forming the immediately preceding intermediate layer 200.

For example, the second layer 108 of InP may be grown by providing a consistent flow of indium and phosphorous. Accordingly, to grow the second layer 108 of InP from the fifth intermediate InGaAsP layer 200-5, the flow rates of gallium and arsenic may be reduced to zero, and the flow rates of indium and phosphorous may be adjusted according to the prescribed flow rate for the specific elemental composition of InP used for the second semiconductor material.

As described above, a semiconductor device having an epitaxial structure with a graded depletion region is described. In particular, the semiconductor device includes an interface region disposed between two semiconductor materials, substantially spanning the expected depletion region of an interface between the two semiconductor materials. The interface region is graded from one semiconductor material to the other to reduce the influence of the bandgap between the two semiconductor materials on recombination in the depletion region. In particular, the interface region may include at least one alloy of the two semiconductor materials. The interface region may include a step-wise gradation, and hence is formed of distinct layers of specific alloys having predetermined elemental compositions. The bandgap is therefore graded. In other examples, the interface region may be linearly graded to provide a graded bandgap.

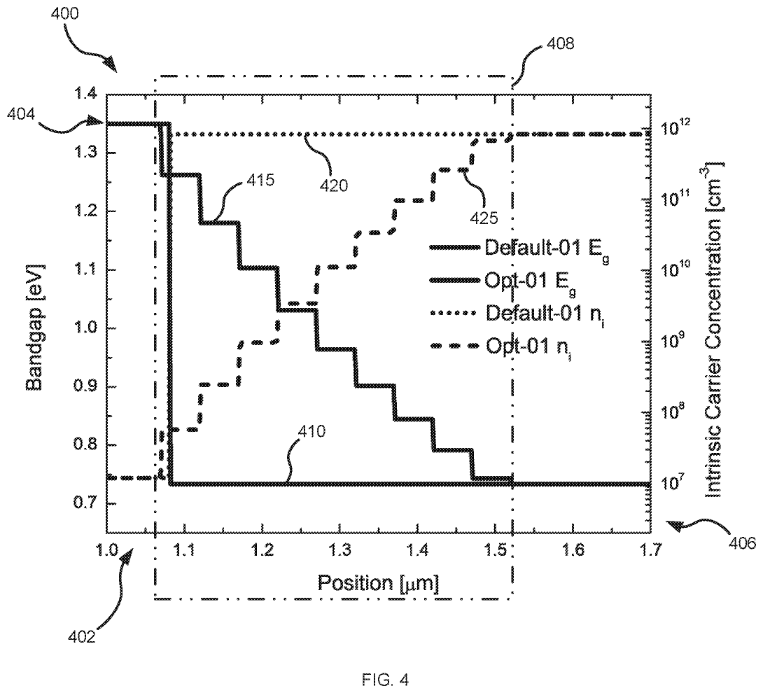

For example, referring to FIG. 4, a plot 400 is depicted. The plot 400 depicts, on the axis 402, the position relative to an end of one of layers of semiconductor materials in micrometers (μm), on the axis 404, the bandgap of a material in electronvolts (eV), and on the axis 406, the intrinsic carrier concentration of a material in units of electrons per cubic centimeter (cm⁻³).

The plot 400 depicts a line 410 (labeled Default-01 E_{g}) representing the bandgap of the materials according to position in the cell, in a cell with a classical p-n junction, such as the cell 150. As can be seen, the bandgap experiences a sharp drop at the interface between the two semiconductor materials. The majority of a depletion region 408 has a low bandgap. The plot 400 also depicts a line 420 (labelled Default-01 nᵢ) representing the intrinsic carrier concentration of the materials according to position in the cell, in a cell with a classical p-n junction, such as the cell 150. As can be seen, the intrinsic carrier concentration experiences a similar sharp change at the interface between the two semiconductor materials. The majority of the depletion region 408 has a relatively high intrinsic carrier concentration due to the low bandgap of the first material 104.

These two factors, low bandgap and high intrinsic carrier concentration within the depletion region 408 contribute to the vulnerability of the depletion region 408 to recombination, and in particular, Shockley-Read-Hall recombination.

The plot 400 also depicts a line 415 (labelled Opt-01 E_{g}) representing the bandgap of the materials according to position in the cell, in a cell with an epitaxial structure as described herein, such as the cell 102. As can be seen, the bandgap is graded from the high bandgap semiconductor material to the lower bandgap semiconductor material and has distinct steps based on the intermediate layers between the two semiconductor materials. The depletion region 408 therefore generally has a much higher average bandgap. The plot 400 also depicts a line 425 (labelled Opt-01 nᵢ) representing the intrinsic carrier concentration of the materials according to position in the cell, in a cell with the epitaxial structure as described herein, such as the cell 102. As can be seen, the intrinsic carrier concentration is similarly graded from the low intrinsic carrier concentration to the relatively higher intrinsic carrier concentration. Thus the intrinsic carrier concentration in the depletion region 408 is on average, exponentially lower.

These lower intrinsic carrier concentration within the depletion region 408 reduces the prevalence of recombination in the depletion region. In particular, by grading the depletion region, no sharp changes in bandgap or intrinsic carrier concentration are experienced. Thus, the graded intermediate layers forming the interface region spanning the depletion region 408 between the two semiconductor materials substantially reduce recombination in the depletion region 408.

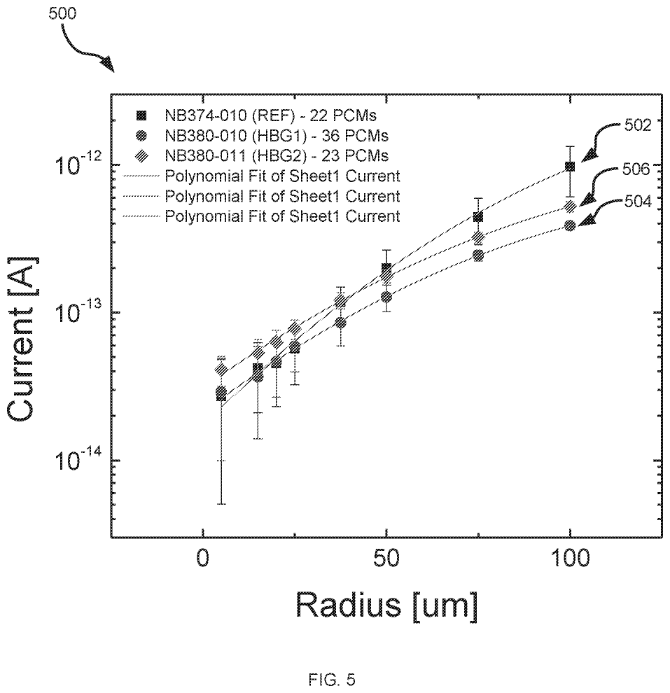

Such a structure is particularly effective in cells having a relatively small perimeter-to-area ratio. For example, referring to FIG. 5, a plot 500 is depicted. The plot 500 charts the dark current detected in cells of different radii. In particular, the plot 500 includes points 502, indicated by square symbols (labelled REF) and representing cells having a classical p-n junction structure, points 504, indicated by circular symbols (labelled HBG1) and representing cells having a first epitaxial structure according to the present specification, and points 506, indicated by diamond symbols (labelled HBG2) and representing cells having a second epitaxial structure according to the present specification.

As can be seen, at small radii (e.g., cells having a perimeter-to-area ratio upwards of about 10000 per centimeter), the dark current experienced by cells with a classical p-n junction structure and cells with the presently described epitaxial structure is similar. As the radius increases, the dark current experienced by cells having the presently described epitaxial structure is significantly lower than the dark current experienced by cells having a classical p-n junction structure. For example, at a radius of 50 μm and larger, the dark current experienced by cells of the current epitaxial structure (HBG1 and HBG2 cells) is between about 30% to about 60% lower than the dark current experienced by the reference cells having the classic p-n junction structure (REF cells).

Accordingly, in a photodetector, preferably the detector cells (i.e., each cell forming a pixel of the photodetector) employing the presently described epitaxial structure are larger, having a perimeter-to-area ratio of less than about 5000 per centimeter, and further preferably, less than about 1000 per centimeter. For example, the epitaxial structure may be used in large area detectors, having, for example a 1D array of detectors, pixels having a large height, single discrete photodetectors with a large area, or the like.

Thus, by grading the interface region, which substantially spans the depletion region, Shockley-Read-Hall recombination is substantially reduced across the depletion region, thereby reducing the dark current experienced in the depletion region and improving performance of semiconductor devices employing this epitaxial structure with a graded depletion region.

The scope of the claims should not be limited by the embodiments set forth in the above examples, but should be given the broadest interpretation consistent with the description as a whole.

1. A semiconductor device comprising:
a first layer comprising a first semiconductor material;
a second layer comprising a second semiconductor material; and
an interface region disposed between the first layer and the second layer and corresponding to an expected depletion region of a junction formed between the first semiconductor material and the second semiconductor material, the interface region comprising a gradation from the first semiconductor material to the second semiconductor material; and
wherein the interface region is configured to reduce Shockley-Read-Hall recombination in the semiconductor device.

2. The semiconductor device of claim 1, wherein the interface region extends substantially across the expected depletion region.

3. The semiconductor device of claim 1, wherein the interface region has a thickness of between about 100 nm and about 1000 nm.

4. The semiconductor device of claim 1, wherein the interface region comprises a stepwise gradation comprising intermediate layers of alloys of the first semiconductor material and the second semiconductor material.

5. The semiconductor device of claim 4, wherein the interface region comprises at least 5 intermediate layers of alloys of the first semiconductor material and the second semiconductor material.

6. The semiconductor device of claim 1, wherein the first semiconductor material comprises indium phosphide and the second semiconductor material comprises indium gallium arsenide.

7. The semiconductor device of claim 6, wherein the interface region comprises at least one alloy of indium gallium arsenic phosphide.

8. The semiconductor device of claim 7, wherein the interface region further comprises at least one alloy of indium gallium arsenic aluminum phosphide.

9. A photodetector comprising:
at least one detector cell, each detector cell comprising:
a semiconductor material having a p-doped region;
an n-type semiconductor material configured to interface with the p-doped region to form a depletion region; and
an interface region contained in the depletion region comprising a gradation of alloys from the semiconductor material to the n-type semiconductor material, the interface region configured to grade a bandgap between the semiconductor material and the n-type semiconductor material and decrease dark current experienced by the photodetector.

10. The photodetector of claim 9, wherein the interface region substantially spans the depletion region of the interface between the p-doped region and the n-type semiconductor material.

11. The photodetector of claim 9, wherein the interface region comprises a step-wise gradation comprising intermediate layers of alloys of the semiconductor material and the n-type semiconductor material.

12. The photodetector of claim 9, wherein a perimeter-to-area ratio of each detector cell is less than about 10000 per centimeter.

13. The photodetector of claim 12, wherein the perimeter-to-area ratio of each detector cell is less than about 1000 per centimeter.

14. The photodetector of claim 9, wherein the semiconductor material comprises indium phosphide and the n-type semiconductor material comprises indium gallium arsenide.

15. The photodetector of claim 14, wherein the interface region comprises at least one alloy of indium gallium arsenic phosphide.
